(19) United States
(12) Patent Application Publication
(10) Pub. No.: US 2025/0279371 A1
(43) Pub. Date: Sep. 4, 2025

(54) FIDUCIAL DESIGNS AND RELATED METHODS FOR WIRE BOND PATTERN RECOGNITION

(71) Applicant: SEMICONDUCTOR COMPONENTS INDUSTRIES, LLC, Scottsdale, AZ (US)

(72) Inventors: Naima WANG, Suzhou (CN); Sen SUN, Suzhou (CN); Ian Ceazar Bucayon BARIAS, Butuan City (PH); Manabu YAJIMA, Ota (JP)

(73) Assignee: SEMICONDUCTOR COMPONENTS INDUSTRIES, LLC, Scottsdale, AZ (US)

(21) Appl. No.: 18/594,145

(22) Filed: Mar. 4, 2024

(51) Int. Cl. G03F 7/00; H01L 23/544

(52) U.S. Cl. CPC G03F 7/70491; G03F 7/70683; H01L 23/544

(57) ABSTRACT

Implementations of a semiconductor device may include a first die pad having a first metal layer thereon; and a fiducial for aligning to the semiconductor device, the fiducial including a portion including a photodefinable material formed over the first metal layer of the first die pad.

### BACKGROUND

### 1. Technical Field

Aspects of this document relate generally to semiconductor devices and methods of manufacturing thereof that improve wire bond pattern recognition. More specific implementations involve including a fiducial on a die pad.

### 2. Background

Semiconductor devices include integrated circuits found in common electrical and electronic devices, such as phones, desktops, tablets, other computing devices, and other electronic devices. Semiconductor packages have been devised that can provide mechanical support and electrical connections to semiconductor devices included therein. Some of these semiconductor packages also provide electrostatic discharge protection and/or humidity protection for the devices.

### SUMMARY

Implementations of a semiconductor device may include a first die pad having a first metal layer thereon; and a fiducial for aligning to the semiconductor device, the fiducial including a portion including a photodefinable material formed over the first metal layer of the first die pad.

Implementations of a semiconductor device may include one, all, or any of the following:
The semiconductor device may include a second die pad adjacent the first die pad, the second die pad having a second metal layer deposited thereon; and a second fiducial formed over the second metal layer.
The semiconductor device may include a space between the first die pad and the second die pad where the second fiducial includes the space.
The fiducial may be formed over an active portion of the first die pad.
The semiconductor device may include a second fiducial for aligning to the semiconductor device, the second fiducial including a photodefinable material formed over the first metal layer of the first die pad.
The fiducial may be triangular.
The fiducial may include a metal alignment feature.
The metal alignment feature may be part of the first metal layer.
The metal alignment feature may be square.
The metal alignment feature may be stepped.
The metal alignment feature may be rectangular.
The metal alignment feature may be triangular.
The metal alignment feature may be spaced apart from an edge of the fiducial.
The photodefinable material may border at least one edge of the fiducial.
The photodefinable material may border at least two edges of the fiducial.

Implementations of a semiconductor device may include a first die pad including a first metal layer; and a second die pad adjacent the first die pad, the second die pad including a second metal layer; and a first fiducial for aligning the semiconductor device, the first fiducial including a photodefinable material formed over one of the first metal layer, the second metal layer, or both the first metal layer and the second metal layer.

Implementation of a semiconductor device may include one, all, or any of the following:
The first fiducial may include a portion of the first metal layer and a portion of the second metal layer.
The semiconductor device may include a second fiducial for aligning the semiconductor device, the second fiducial including a photodefinable material formed over the first metal layer, the second metal layer, or both the first metal layer and the second metal layer.
The semiconductor device may include a third fiducial for aligning the semiconductor device, the third fiducial including a photodefinable material formed over the first metal layer, the second metal layer, or both the first metal layer and the second metal layer.

Implementations of a semiconductor device may include a first die pad; and a second die pad adjacent the first die pad; and a first fiducial for aligning the semiconductor device, the first fiducial including a material formed over one of the first die pad, the second die pad, or both the first die pad and the second die pad.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a top view of an implementation of a semiconductor device including a plurality of fiducials;

FIG. 2 is an enlarged view of plurality of fiducials of FIG. 1;

FIG. 3 is a top view of an implementation of a fiducial on a semiconductor device;

FIG. 4 is a cross sectional side view of the semiconductor device of FIG. 3;

FIG. 5 is a top view of an implementation of fiducials on a semiconductor device;

FIG. 6 is a top view of an implementation of fiducials on a semiconductor device;

FIG. 7 is a top view of an implementation of fiducials on a semiconductor device;

FIG. 8 is a top view of an implementation of fiducials on a semiconductor device;

FIG. 9 is an enlarged partial top view of an implementation of fiducials on a semiconductor device; and

FIG. 10 is a top view of the implementation of fiducials on the semiconductor device of FIG. 9.

### DESCRIPTION

This disclosure, its aspects and implementations, are not limited to the specific components, assembly procedures or method elements disclosed herein. Many additional components, assembly procedures and/or method elements known in the art consistent with the intended semiconductor devices and systems and methods thereof will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor devices and systems and methods thereof, and implementing components and methods, consistent with the intended operation and methods.

During fabrication, wire bonding is the process of bonding wires to the semiconductor devices to connect the semiconductor devices to packaging substrates. Wire bonding machines must be able to accurately place each wire on the semiconductor devices and packaging substrates. Pattern recognition is implemented to identify the proper locations for the wire bond on each semiconductor device to ensure alignment to each semiconductor device takes place properly prior to the wire bonding process.

While wirebonding generally forms electrical connections, in the semiconductor device examples provided herein, the wire bonds are connected on one end to the source pads, also known as die pads, of the semiconductor device and to a substrate or other semiconductor package component on the other end. Other wirebonds are also used to connect other device structures like the gate interconnect to the substrate or other semiconductor package. While the semiconductor device implementations disclosed herein are mostly single devices, such as, by non-limiting example, power transistors, power diodes, insulated gate bipolar transistors (IGBTs), silicon controlled rectifiers (SCRs), or other power semiconductor devices, the principles disclosed herein can also be used to form fiducials for a wide variety of other semiconductor device types, such as, by non-limiting example, microprocessors, controllers, microcontrollers, random access memories, field programmable gate arrays, flash memories, or any other semiconductor device type where wirebonding is employed as an interconnect.

When the wire bonds are not properly connected to the semiconductor source pads, particularly where they bridge or cause shorts to other pads, the semiconductor packages will not function properly. In practice, the wire bonds may be improperly connected to the substrate when the wire bonds are outside the desired source pad area, improperly connected to bus lines, or improperly connected to two source pads, all of which cause electrical shorts or failures.

In wirebonding machines, pattern recognition techniques, software and equipment are used to detect a pattern that may include, for example, a fiducial or a plurality of fiducials on a semiconductor device, to accommodate for variations in alignment of each semiconductor device so a wire bond may be placed in a desired location on the source pads.

Fiducials are embedded objects, surface marks, or optically transmissive/partially optically transmissive layers that serve as a known reference point on a semiconductor device. A set of fiducials is used during alignment processing for image and pattern recognition techniques and systems used in wirebonders. The pattern recognition systems use the placement of the set of fiducials as reference points to determine the alignment and/or adjust the alignment of the semiconductor die itself so that the pre-programmed coordinates the wirebonder uses to place the wirebonds lead to formation of wirebonds at the desired locations on the semiconductor device. The fiducials aid in ensuring the semiconductor device or the wirebonding head(s) is oriented properly and so variations in direction and skew are comprehended.

With regard to the wire bonding process, slight variations in the orientation of the semiconductor device with respect to the wire bonding equipment may be sufficient to ruin the electrical connections of the packaged semiconductor device, particularly where small pads or pads with a fine pitch are involved. As a result, fiducials are included on the semiconductor device to aid in aligning the placement of the wire bonds and other components with each semiconductor device. During wirebonding, the fiducials are first located, then the position of the bond head may be adjusted or the semiconductor device adjusted (or both) to adjust the placement of the wire bonds and other components to accommodate for variations in the exact position of each individual semiconductor device on the manufacturing line. Fiducials that can be easily and accurately recognized by the wirebonder thus are an important part of the manufacturing process because the precise placement of wire bonds and components with respect to the semiconductor device is important to avoiding failure in the as-assembled semiconductor packages.

To assist with various alignment algorithms employed by wirebonders, fiducials are often located at the corners or around a perimeter of the semiconductor devices. A one-point fiducial pattern includes using one point in a pattern of the semiconductor die as a reference point, whereas a two-point fiducial pattern includes using two separated points in the pattern as the reference points. In some method implementations, three or more reference points may be employed. While in some circumstances, using a fiducial pattern with one point of reference, such as a gate pad, may be sufficient, fiducial patterns that cover two points of reference physically separated from one another may be more accurate and result in better wire bond and component placement. Two-point fiducial patterns, specifically when located on a diagonal with respect to each other, may provide increased accuracy because the two-point fiducial patterns are able to compensate for die rotation and tilt. Using two-point fiducial patterns in pattern recognition techniques may also further assist with accurate alignment and prevent improper placement of the wire bonds. For some semiconductor devices, some two-point fiducial pattern recognition techniques include using a gate pad as a first fiducial and the “T” intersection of the bus line between two source pads to identify a position and alignment of the semiconductor device including any skew and/or rotation thereof.

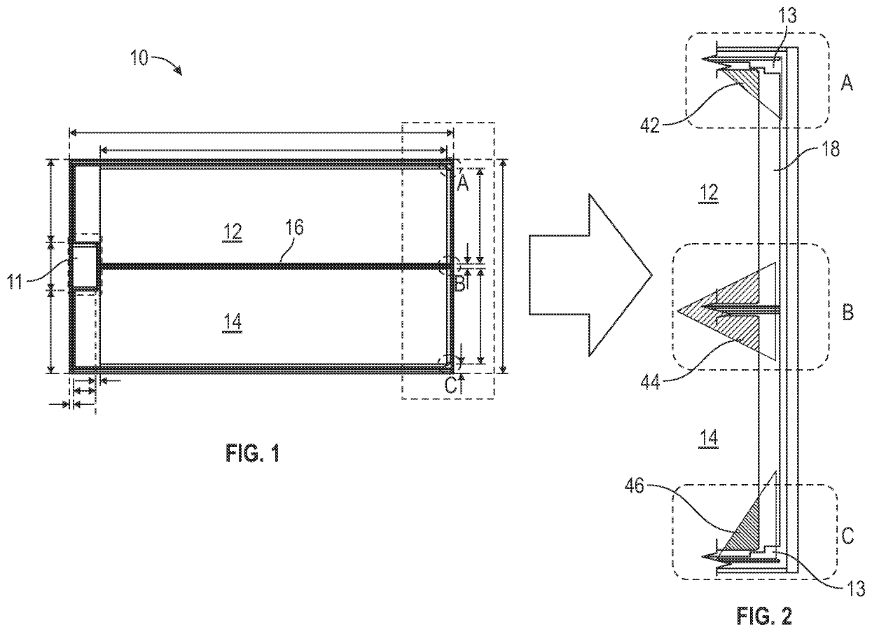

Referring to FIGS. 1 and 2, top views of an implementation of a semiconductor device including a plurality of fiducials are illustrated. Semiconductor device 10 includes a plurality of source pads 12, 14 adjacent each other and separated by a gap/space, source street 16 that provides electrical isolation between the two pads. Device 10 also includes a gate pad 11 and source runner 18. Gate pad 11 is disposed adjacent source pads 12, 14 on one end of semiconductor device 10. Source runner 18 surrounds source pads 12, 14 on this side of the semiconductor device and is covered by passivation material, which may be polyimide material in various implementations. In some implementations, the source runner 18 is present at a uniform thickness around a perimeter of source pads 12, 14. As illustrated, metal fiducials 13 are located in upper and lower corners at positions A and C as illustrated by the dotted line regions in FIGS. 1 and 2 with an additional fiducial pattern formed as the entire outline of the gate pad 11 (shown in dotted lines in FIG. 1). Here we have a two-point fiducial pattern between the gate pad fiducial and the metal fiducials 13 on each side of the semiconductor device. As illustrated, in some implementations the metal fiducials 13 are stepped rectangular features at aid in distinguishing their outline from the surrounding metal structure. As previously discussed, semiconductor device 10 may be a power semiconductor device including, by non-limiting example, a metal oxide field effect transistor (MOSFET), an insulated gate bipolar transistor (IGBT), a diode, a thyristor, a silicon controlled rectifier (SCR), or any other kind of power semiconductor device. Source pads 12, 14, are used to connect the source of the semiconductor device to the corresponding source interconnect(s) of the semiconductor package. In the particular device illustrated in FIG. 1, the larger the source pads are, the better performance is achieved for the semiconductor package so the size of the source pads is maximized on this side of the semiconductor device. However, this means that little space is reserved for the formation of fiducial structures, particularly metal fiducial structures.

Referring still to FIGS. 1 and 2, FIGS. 1 and 2 illustrate implementations of fiducials 42, 44, 46 arranged on top of source pads 12, 14. Fiducials 42, 44, 46 are used, either individually or collectively, to align semiconductor device 10 with respect to wire bonding equipment during a wire bonding process to promote desired placement of wire bonds and/or other components. While the use of three different fiducials 42, 44, 46 is illustrated in FIGS. 1 and 2, only one of the fiducials, two of the fiducials, or more than three fiducials could be used in other implementations, Fiducials 42, 44, 46 may be formed from a photodefinable material that is fully or partially optically transmissive allowing the alignment camera to see through the fiducial while detecting the change in color/pattern the fiducial creates. The photodefinable material may be, by non-limiting example, a photolithographic material, a polyimide, a photosensitive polyimide, or a fully or partially optically transmissive material. In some implementations, the fiducials 42, 44, 46 may be a patterned layer over a metal layer and other underlying structures in the semiconductor die. In other implementations, the fiducials 42, 44, 46 may be formed of an oxide or nitride material and/or be etched using a pattern formed from a photodefinable material like photoresist.

In various implementations, the fiducials 42, 44, 46 may be arranged over the source pads 12, 14, source street 16, source runner 18 and/or metal fiducials 13. As illustrated in FIGS. 1 and 2, fiducial 42 is arranged in an upper right corner at position A of semiconductor device 10 and aligned on a diagonal with respect to gate pad 11. Fiducial 42 overlays source runner 18, source pad 12 and metal fiducial 13 and has a right triangular geometry and is partially optically transmissive. This results in a change in color of the underlying structures below the structure of the fiducial which the alignment camera of a wirebonder can detect. Fiducial 44 is arranged on an end of source street 16, opposite gate pad 11 at position B. Fiducial 44 overlays source street 16, source runner 18 and source pads 12 and 14 and has a substantially equilateral triangular geometry. Fiducial 46 is arranged in a lower right corner at position C of semiconductor device 10 and aligned on a diagonal with respect to gate pad 11. Fiducial 46 overlays source runner 18, source pad 14 and metal fiducial 13 and has a right triangular geometry.

Fiducials 42, 44, 46 may be formed of a wide variety of closed shapes that have features that are able to be uniquely identified and can be used in alignment algorithms to allow for calculation of skew and/or rotation of the semiconductor die. For example, while circular shapes could be used, they may not perform as well as straight edged shapes like Y-shaped features, crosses, concave polygons, star-shaped features and other. However, where the shape of the fiducial is used in combination with another adjoining or underlying structure that helps provide an orientation like the source running, the use of convex polygons and elliptical shapes could also be used. In various implementations, the same or different fiducial shapes may be employed where multiple fiducials are used.

When using a multi-point pattern recognition method or technique that includes gate pad 11 as one reference pattern/point, positioning at least one additional fiducial 42, 44, 46 (or the group of two or all three of the fiducials) as the second reference pattern/point across from gate pad 11 instead of, for example, on a same side as gate pad 11, may provide increased accuracy and better bonding results due to increased ability to detect rotation/skew of the semiconductor device. In addition, when using a multi-point pattern recognition method or technique that includes gate pad 11 as one point/pattern, positioning a second fiducial on a diagonal with respect to the first point/pattern, gate pad 11, may also provide increased alignment accuracy and thus better bonding results. Thus, in some implementations, using fiducials 42, 46 at positions A or C in conjunction with gate pad 11 in a two-point pattern may be beneficial. Further, when using a three-point pattern recognition method or technique that includes three fiducials, arranging the fiducials in a triangular shape may also provide increased accuracy and better bonding results. Thus, in further implementations, using fiducials 42, 46 at positions A and C in conjunction with gate pad 11 in a three-point triangular pattern may be beneficial.

In some implementations, fiducials 42, 44, 46 are created using photolithography and masking methods from photodefinable materials. A layer of photodefinable material, photosensitive material, photoresist, or other material may be deposited on the semiconductor device 10 during the end of the semiconductor fabrication process. A mask, including the pattern for the desired fiducials is used to expose the photodefinable material and light is transmitted through the mask. The pattern of the mask is transferred into the photodefinable material which is then developed to remove the exposed or unexposed portions (depending on the type of photodefinable material used) leaving behind the desired fiducials. Additional baking and/or curing steps may be employed to ensure the photodefinable material is fully stabilized and ready to remain on the semiconductor die through the packaging process. In other implementations, oxides or nitrides that are not be photodefinable themselves are initially deposited on semiconductor device 10, and subsequently patterned using photodefinable materials like photoresist followed by etching processes resulting in fiducials with a pattern etched into the material of the oxide/nitride.

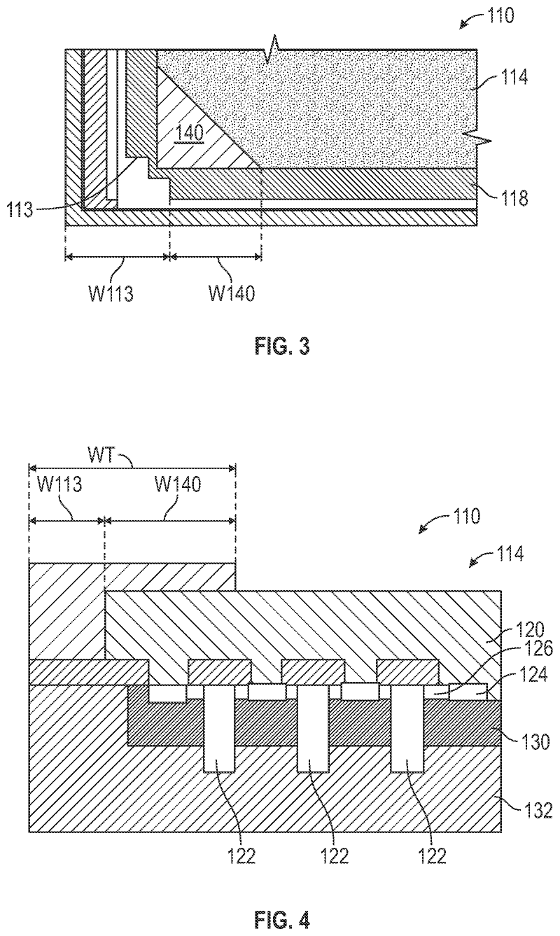

As illustrated in FIGS. 3 and 4, a portion of a semiconductor device 110 comprising a source pad 114, source runner 118, a source or metal layer 120 is illustrated. As illustrated in FIG. 4, the semiconductor device has a semiconductor substrate that may have doped regions formed within the substrate to form an active (p) layer 130 and a passive (n) layer 132. Gates 122 are arranged between channels 126 and sources/drains 124. When a positive voltage is applied to gate 122, negative electrons flow from the source 124 and drain through channels 126 allowing a current to pass through. Electricity flows from the source to the drain during operation of the device. As illustrated in FIG. A metal fiducial 113 is provided in a lower corner of the semiconductor device 110. The metal fiducial 113 is shown having a stepped geometry formed by stepping the corner of the source pad, creating a corresponding space that is darker when viewed by the camera than the more reflective metal.

One solution for improving wire bond setting include enlarging metal fiducial 113 on the die corner for better wire bond pattern recognition by making the space adjoining the source pad larger. However, enlarging the metal fiducial reduces the size of the source metal layer 120 which can affect electrical performance because the electrical structure (gates/channels/drains) underneath the source metal layer 120 may be exposed which can create reliability risk. In addition, changing the size of the metal fiducial includes changing the mask used to create the metal fiducial 113 which is itself a costly process.

In contrast, FIGS. 3 and 4, illustrate forming a fiducial 140 using a photodefinable material deposited over source pad 114, specifically, over source or metal layer 120. As illustrated in FIG. 3, because the photodefinable material is partially optically transmissive, it creates a different colored/contrasting pattern at the corner of the source pad that complements or works with the existing fiducial shape. In some implementations, the use of the fiducial 140 may replace or eliminate the need to use the metal fiducial 113.

In some implementations, the photodefinable fiducial is a photosensitive material such as a polyimide, for example, which is already patterned on the surface of the semiconductor device where the fiducial 140 is formed by adjusting the mask pattern used to form the polyimide layer. As illustrated in FIGS. 3 and 4, metal fiducial 113 provides a fiducial width of W₁₁₃ available for pattern recognition detection. By applying photodefinable fiducial 140 over metal layer 120, an additional width, width W₁₄₀, is available for pattern recognition detection in addition to width W₁₁₃. Thus, a total width available for pattern recognition is increased from width W₁₁₃ by with W₁₄₀ to a total fiducial width, width W_{T}. The increase in the width comes with an increase the total area of the fiducial and the additional of an additional shape(s) that the alignment camera can use during pattern recognition. Also, applying a photosensitive fiducial 140 over top of the source pad layer 120 increases the width/area/shape available for pattern recognition without altering or changing the underlying active area, source pad layer 120, source pad 114, or electrical parameters of semiconductor device 110. The increased width/area/shape improves detection and analysis by pattern recognition techniques and modalities. The photodefinable layer including fiducial 140 may be formed on the surface of semiconductor 110 at the last or one of the last process steps, thus making fiducial 140 easy and simple to fabricate without affecting the function and reliability of semiconductor device 110. In addition, fiducial 140 may be deposited over an active region of the source pad as illustrated in FIG. 4 without impacting the electrical characteristics of the semiconductor device 110.

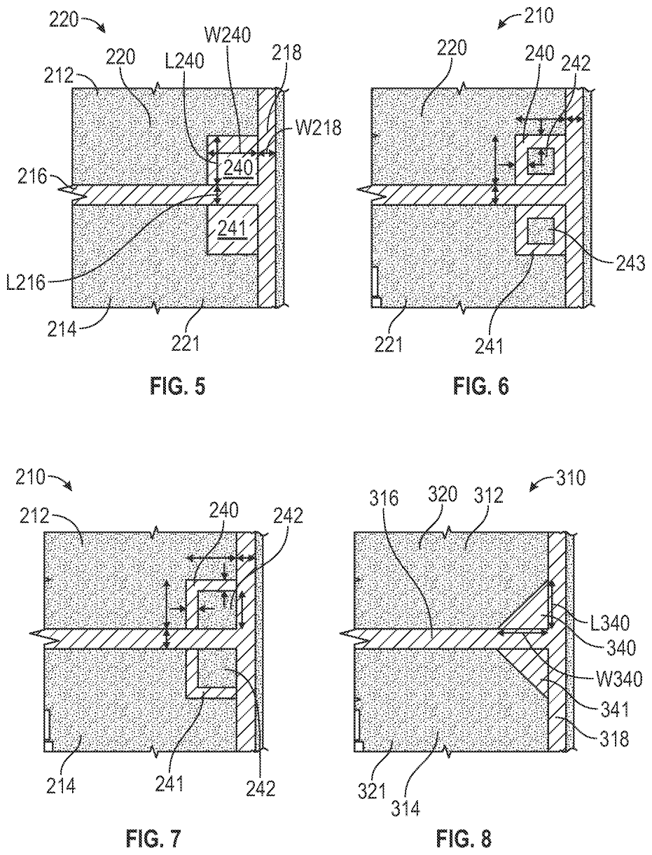

FIGS. 5 to 7 illustrate portions of semiconductor devices 210 with fiducials 240, 241 formed on metal layers 220, 221 of source pads 212, 214 respectively. Source pads are separated by a space and/or a non-active area, source street 216 which acts to electrically insulate the source pads 212, 214 from each other. Source runner 218 surrounds a perimeter of source pads 212, 214. Each source pad 212, 214 includes metal layer 220, 221, respectively. Fiducials 240, 241 are made of a photodefinable material which, in some implementations, may include photosensitive materials such as a polyimide, or any other photodefinable material type disclosed in this document. As illustrated in FIGS. 5 to 7, fiducials 240 are located in a lower corner of source pads 212 and fiducials 241 are located in an upper corner of source pads 214. Fiducials 240, 241 are illustrated as being rectangular or square in shape but can include any desired geometry. Fiducial 240 includes a length L₂₄₀ and a width W₂₄₀, source street includes a length L₂₁₆ and source runner 218 includes a width W₂₁₈. As illustrated in FIG. 5, fiducial 240 includes a width W₂₄₀ of 200 microns and a length L₂₄₀ of 200 microns, source runner 218 has a width₂₁₈ of 73 microns and source street 216 has a length of L₂₁₆ of 82 microns. In some implementations, a single fiducial pattern used for alignment may encompass fiducials 240, 241 and/or a portion of source street 216 having the photodefinable material formed thereon. In various implementations, a single fiducial pattern used during alignment may encompass fiducials 240, 241 and the areas of source runner 218 and/or source street 216 having the photodefinable material deposited thereon resulting in a fiducial having a width that is 275 micrometers wide or less and a length of that is 500 microns or less. In some implementations, the fiducials 240, 241 overlap the source pad by 200 microns in width and/or length. In some implementations, fiducials 240, 241 may be utilized as one fiducial extending across two source pads 212, 214 and source street 216. The dimensions of the fiducial structures here are merely for the exemplary purposes of this disclosure as smaller or larger fiducials are possible using the principles disclosed herein.

FIGS. 6 and 7 illustrate fiducials 240, 241 that include metal alignment features 242, 243 as part of the fiducial structure. The metal alignment features 242, 243 may be located within a perimeter or of fiducials 240, 241, may be spaced apart from a perimeter of fiducials 240, 241 as illustrated in FIG. 6, or aligned with at least one edge of fiducials 240, 241 as illustrated in FIG. 7. FIG. 6 illustrates metal alignment features 242, 243 floating within a perimeter of fiducials 240, 241 respectively, such that the metal alignment features 242, 243 are spaced apart from each edge of fiducials 240, 241, respectively. In some implementations, the metal alignment features 242, 243 may be floating within fiducials 240, 241, respectively, and, for example, may be spaced apart from each edge of fiducials 240, 241 by 50 microns or less though larger or smaller distances could be used in various implementations.

FIG. 7 illustrates metal alignment features 242, 243 in which the metal alignment features 242, 243 border two edges of fiducials 240, 241, respectively and photodefinable material borders two edges of fiducials 240, 241, forming part of the same layer of photodefinable material that forms the fiducials 240, 241. In some implementations, metal alignment features 242, 243 may be spaced apart from at least one edge of fiducials 240, 241 by 50 microns or less. In various implementations, a metal alignment feature 242, 243 may border at least one edge of a fiducial 240, 241, respectively.

A length and a width of metal alignment features 242, 243 maybe 150 microns or less in a particular implementation. The metal alignment features 242, 243 may be any shape disclosed herein for a fiducial. Here the shape of the metal alignment features is square. In some implementations, metal alignment features 242, 243 may be made of the source metal layer 220, 221, respectively whereas in other implementations, metal alignment features 242, 243 may be formed of a separate layer of metal. As illustrated in FIGS. 5-7, the metal alignment features 242, 243 are optically visible through the material of their respective fiducials. Photolithography and masking methods may be used to form fiducials 240, 241 having the desired metal alignment features 242, 243 either at the same time as the source metal layer or afterward.

FIG. 8 illustrates a semiconductor device 310 comprising fiducials 340, 341 formed on metal layers 320, 321 of source pads 312, 314 respectively. Source pads 312, 314 are separated by a space and/or a non-active area, source street 316 used to provide electrical isolation between the source pads 32, 314. As illustrated, source runner 318 surrounds a perimeter of source pads 312, 314. Each source pad 312, 314 includes/is composed of a metal layer 320, 321, respectively. Fiducials 340, 341 are comprised of a photodefinable material which, in some implementations, includes photosensitive materials such as polyimide or any other photosensitive material like those disclosed in this document. As illustrated in FIG. 8, fiducial 340 is located in a lower corner of source pad 312 and fiducial 341 is located in an upper corner of source pad 314. Fiducials 340, 341 are illustrated as being triangular in shape but can include any shape disclosed in this document. Here they take the form of a right triangles. Fiducial 340 includes a length L₃₄₀ and a width W₃₄₀, the length L₃₄₀ and width W₃₄₀ may each be 200 microns or less in a particular implementation. What is different about the fiducials 340, 341 of FIG. 8 from those in FIGS. 6 and 7 is that there is no patterning of the metal layer of the source pads 312, 314, but the shape of the fiducial is formed just using the photodefinable material or patterned oxide/nitride layer. This is a similar approach to the fiducials 240, 241 of FIG. 5, which are rectangular.

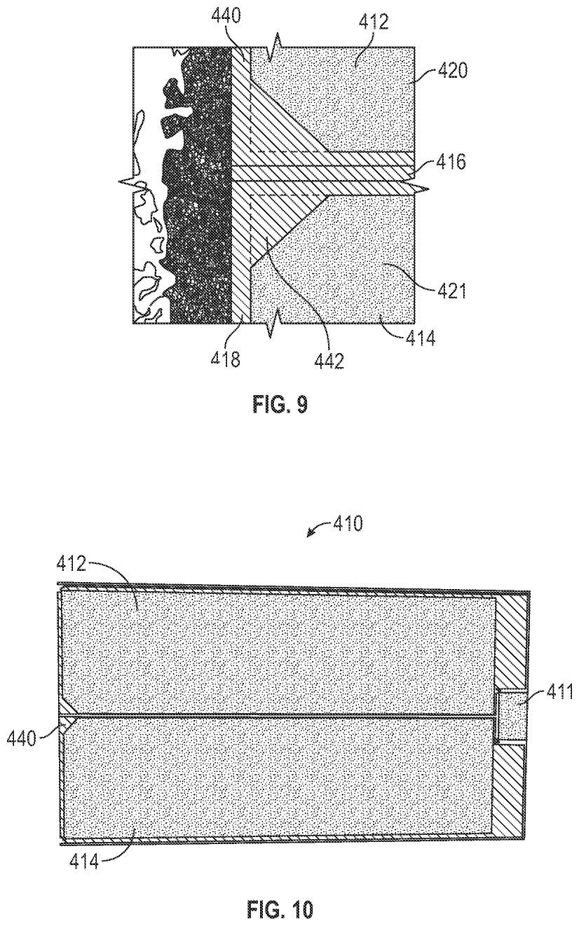

FIGS. 9 and 10 illustrate top views at different magnifications of the implementation of fiducial 440 formed over source pads 412, 414 of a semiconductor device 410. Semiconductor device 410 includes gate pad 411, source pads 412, 414 separated by gate runner 416. Source runner 418 also surrounds a perimeter of source pads 412, 414. As illustrated in FIG. 9, fiducial 440 is formed of a pattern formed in a photodefinable material deposited over source pads 412, 414, gate runner 416 and source runner 418 that equipment may be like any disclosed in this document, but in this case is in the form of two right triangles opposing each other across the width of the gate runner 416. Fiducial 440 includes a triangular shape overlapping source pads 412, 414 which, along with the shape of a portion of the source street contrasting with the source pad material, results in better wire bond placement than a “T” shaped fiducials formed at the intersection of the source street and source runner because this shape is more reliably recognized by the image recognition software than the shape of just the corners of the source pads and portion of the source street alone. Fiducial 440 may be formed using photolithography and masking techniques disclosed herein for use in forming photodefinable materials and oxides/nitrides.

In places where the description above refers to particular implementations of semiconductor devices and implementing components, sub-components, methods and sub-methods, it should be readily apparent that a number of modifications may be made without departing from the spirit thereof and that these implementations, implementing components, sub-components, methods and sub-methods may be applied to other semiconductor devices.

What is claimed is:

1. A semiconductor device comprising:
a first die pad having a first metal layer thereon; and
a fiducial for aligning to the semiconductor device, the fiducial comprising a portion comprising a photodefinable material formed over the first metal layer of the first die pad.

2. The semiconductor device of claim 1, further comprising:
a second die pad adjacent the first die pad, the second die pad having a second metal layer deposited thereon; and
a second fiducial formed over the second metal layer.

3. The semiconductor device of claim 2, further comprising:
a space between the first die pad and the second die pad wherein the second fiducial includes the space.

4. The semiconductor device of claim 1, wherein the fiducial is formed over an active portion of the first die pad.

5. The semiconductor device of claim 1, further comprising:
a second fiducial for aligning to the semiconductor device, the second fiducial comprising a photodefinable material formed over the first metal layer of the first die pad.

6. The semiconductor device of claim 1, wherein the fiducial is triangular.

7. The semiconductor device of claim 1, wherein the fiducial comprises a metal alignment feature.

8. The semiconductor device of claim 7, wherein the metal alignment feature is part of the first metal layer.

9. The semiconductor device of claim 7, wherein the metal alignment feature is square.

10. The semiconductor device of claim 7, wherein the metal alignment feature is stepped.

11. The semiconductor device of claim 7, wherein the metal alignment feature is rectangular.

12. The semiconductor device of claim 7, wherein the metal alignment feature is triangular.

13. The semiconductor device of claim 7, wherein the metal alignment feature is spaced apart from an edge of the fiducial.

14. The semiconductor device of claim 7, wherein the photodefinable material borders at least one edge of the fiducial.

15. The semiconductor device of claim 14, wherein the photodefinable material borders at least two edges of the fiducial.

16. A semiconductor device comprising:
a first die pad comprising a first metal layer; and
a second die pad adjacent the first die pad, the second die pad comprising a second metal layer; and
a first fiducial for aligning the semiconductor device, the first fiducial including a photodefinable material formed over one of the first metal layer, the second metal layer, or both the first metal layer and the second metal layer.

17. The semiconductor device of claim 16, wherein the first fiducial includes a portion of the first metal layer and a portion of the second metal layer.

18. The semiconductor device of claim 16, further comprising:
a second fiducial for aligning the semiconductor device, the second fiducial including a photodefinable material formed over the first metal layer, the second metal layer, or both the first metal layer and the second metal layer.

19. The semiconductor device of claim 18, further comprising:
A third fiducial for aligning the semiconductor device, the third fiducial including a photodefinable material formed over the first metal layer, the second metal layer, or both the first metal layer and the second metal layer.

20. A semiconductor device comprising:
a first die pad; and
a second die pad adjacent the first die pad; and
a first fiducial for aligning the semiconductor device, the first fiducial including a material formed over one of the first die pad, the second die pad, or both the first die pad and the second die pad.
